(19) United States
(12) Patent Application Publication
(10) Pub. No.: US 2026/0335945 A1
(43) Pub. Date: Oct. 29, 2026

(54) METHOD FOR CLEANING A SUBSTRATE CHUCK USING A CLEANING SUBSTRATE

(71) Applicant: SAMSUNG ELECTRONICS CO., LTD., Suwon-si (KR)

(72) Inventor: Hyungjun KIM, Suwon-si (KR)

(73) Assignee: SAMSUNG ELECTRONICS CO., LTD., Suwon-si (KR)

(21) Appl. No.: 19/370,156

(22) Filed: Oct. 27, 2025

(30) Foreign Application Priority Data
Apr. 23, 2025 (KR) 10-2025-0053180

(51) Int. Cl. B08B 7/00

(52) U.S. Cl. CPC B08B 7/0028; B08B 2240/00

(57) ABSTRACT

A method for cleaning a substrate chuck includes: loading a cleaning substrate into a transfer module, the cleaning substrate including an electrostatic control layer and an adhesive layer disposed on one surface of the electrostatic control layer; loading the cleaning substrate from the transfer module into a transfer chamber connected to the transfer module; loading the cleaning substrate from the transfer chamber into one of a plurality of processing chambers connected to the transfer chamber, a processing chamber of the plurality of processing chambers including the substrate chuck; controlling the cleaning substrate so that the adhesive layer contacts the substrate chuck; and unloading the cleaning substrate from the processing chamber.

### CROSS-REFERENCE TO RELATED APPLICATION

This application claims priority to Korean Patent Application No. 10-2025-0053180, filed on Apr. 23, 2025, in the Korean Intellectual Property Office, the disclosure of which is incorporated by reference herein in its entirety.

### BACKGROUND

The present disclosure relates to a method for cleaning a substrate chuck, and more particularly, to a method for removing contaminant particles from a substrate chuck.

Recently, due to demand for high integration of semiconductor devices and improved power efficiency, a thickness of a wafer is decreasing to a level of tens of micrometers (μm). As a result, the possibility of mechanical strength degradation of the wafer and defects caused by external particles during the manufacturing process is greatly increasing. In particular, fine particles remaining on a surface of a device supporting the wafer, such as a vacuum chuck or an electrostatic chuck, may cause indentations, scratches, and particle defects on a back surface of the wafer, which can directly affect yield reduction and device reliability.

### SUMMARY

One or more example embodiments provide a method for cleaning a substrate chuck having improved dust collection characteristics.

According to an aspect of an example embodiment, a method for cleaning a substrate chuck includes: loading a cleaning substrate into a transfer module, the cleaning substrate including an electrostatic control layer and an adhesive layer disposed on one surface of the electrostatic control layer; loading the cleaning substrate from the transfer module into a transfer chamber connected to the transfer module; loading the cleaning substrate from the transfer chamber into one of a plurality of processing chambers connected to the transfer chamber, a processing chamber of the plurality of processing chambers including the substrate chuck; controlling the cleaning substrate so that the adhesive layer contacts the substrate chuck; and unloading the cleaning substrate from the processing chamber.

According to another aspect of an example embodiment, a method for cleaning a substrate chuck includes: loading a cleaning substrate into one of a plurality of processing chambers, the cleaning substrate including an electrostatic control layer and an adhesive layer disposed on one surface of the electrostatic control layer, and a processing chamber of the plurality of processing chambers including the substrate chuck; controlling the cleaning substrate so that the adhesive layer contacts the substrate chuck; and reciprocally moving the cleaning substrate in any one or any combination of a vertical direction or a horizontal direction with respect to the support surface of the substrate chuck.

According to another aspect of an example embodiment, a method for cleaning a substrate chuck includes: loading a cleaning substrate having a ring frame attached thereto into a processing chamber in which the substrate chuck is disposed; and reciprocally moving the cleaning substrate in any one or any combination of a vertical direction or a horizontal direction on the substrate chuck. The cleaning substrate includes an electrostatic control layer, and an adhesive layer between the electrostatic control layer and the substrate chuck. The electrostatic control layer includes a composite dielectric layer and conductive nanoparticles.

### BRIEF DESCRIPTION OF DRAWINGS

The above and other aspects, features, and advantages will be more apparent from the following description of example embodiments, taken in conjunction with the accompanying drawings, in which:

FIGS. 1A and 1B are perspective views of cleaning substrates according to example embodiments;

FIGS. 2A and 2B are views illustrating an electrostatic control layer according to example embodiments;

FIGS. 3 and 4 are graphs illustrating a dielectric constant and self-generated voltage of an electrostatic control layer of an example embodiment;

FIG. 5 is a flow chart illustrating a method for cleaning a substrate chuck according to an example embodiment;

FIGS. 6-9 are views illustrating a method for cleaning a substrate chuck according to an example embodiment;

FIG. 10A is a flow chart illustrating a method for removing contaminant particles from a substrate chuck according to an example embodiment, and FIG. 10B is a view illustrating a process consistent with FIG. 10A;

FIGS. 11A, 11B, 11C, and 11D are views illustrating the process for removing contaminant particles according to an example embodiment;

FIG. 12A is a flow chart illustrating a method for removing contaminant particles from a substrate chuck according to an example embodiment, and FIG. 12B is a view illustrating a process consistent with FIG. 12A; and

FIGS. 13A, 13B, and 13C are views illustrating a process of removing contaminant particles according to an example embodiment.

### DETAILED DESCRIPTION

Hereinafter, example embodiments of the present disclosure will be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Unless otherwise specified, in this specification, terms such as ‘upper portion,’ ‘upper surface,’ ‘lower portion,’ ‘lower surface,’ ‘side surface’, and the like are based on the drawings, and actually, may vary depending on the direction in which the components are disposed. It will be also understood that, even if a certain operation of manufacturing an apparatus or structure is described later than another operation, the operation may be performed later than the other operation unless the other operation is described as being performed after the operation. The same reference numerals are used to denote the same elements in the drawings, and repeated descriptions thereof will be omitted.

In addition, ordinal numbers such as “first,” “second,” “third,” and the like may be used as labels for specific elements, operations, directions, and the like to distinguish various elements, operations, directions, and the like from each other. Terms that are not described using “first,” “second,” and the like in the specification may still be referred to as “first” or “second” in the claims. In addition, terms referenced by a particular ordinal number (for example, “first” in a particular claim) may be described elsewhere with a different ordinal number (for example, “second” in the specification or another claim).

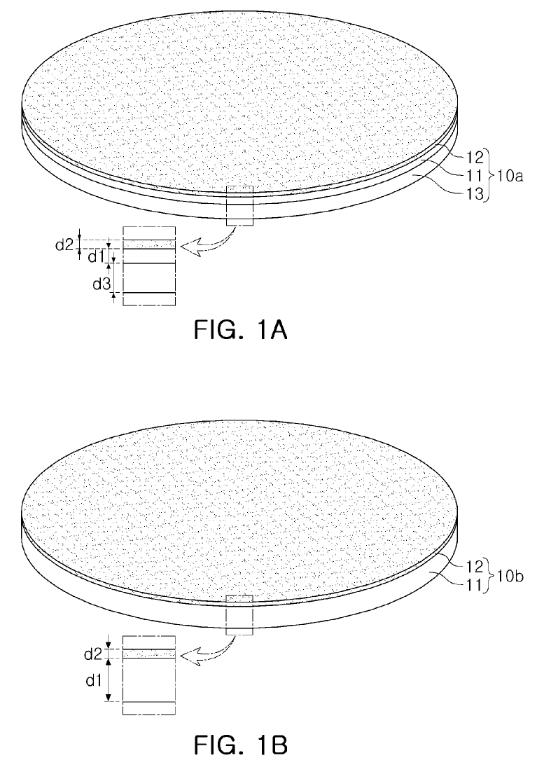

FIGS. 1A and 1B are perspective views of cleaning substrates 10a and 10b according to example embodiments.

Referring to FIG. 1A, the cleaning substrate 10a of an example embodiment may include an electrostatic control layer 11, an adhesive layer 12, and a base film 13. The cleaning substrate 10a may be configured to remove foreign substances (e.g., silicon residue, etc.) attached to a surface of a chuck which supports and fixes a semiconductor wafer in a semiconductor process by adhering to the foreign substances. The cleaning substrate 10a may have a shape similar to a semiconductor wafer. The cleaning substrate 10a may have a size corresponding to a support surface of the chuck. For example, the cleaning substrate 10a may have a wafer shape, and may be circular with a diameter of 300 mm to 400 mm.

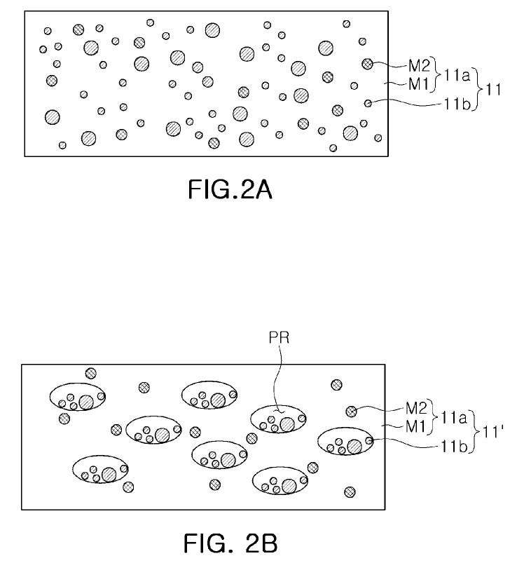

The electrostatic control layer 11 may be configured to have triboelectric nanogenerator (TENG) characteristics. The electrostatic control layer 11 may form a potential without an external power source based on tribo-electrification and electrostatic induction, and therefore may have characteristics of electrostatic control. By including a material composition according to an example embodiment, the electrostatic control layer 11 may induce a local electrostatic field by generating a potential difference through repeated up/down (adhesion/peeling) and left/right (friction) movements. The potential difference or induced charge formed in this case may act in a direction weakening electrostatic attraction between the contaminant particles attached to the support surface and the chuck. Accordingly, the electrostatic control layer 11 may effectively improve cleanliness of the support surface of the chuck by reducing adhesion strength of fine particles and inducing detachment or adhesion of particles. The constituent materials of the electrostatic control layer 11 are described in more detail with reference to FIGS. 2A and 2B.

A thickness (d1) of the electrostatic control layer 11 may be in a range of 10 µm or more, for example, in a range of 10 µm to 50 µm, in a range of 15 µm to 50 µm, in a range of 20 µm to 50 µm, in a range of 25 µm to 50 µm, or the like. When the thickness (d1) of the electrostatic control layer 11 is less than 10 µm, an electrostatic control effect may be reduced. An upper limit of the thickness (d1) of the electrostatic control layer 11 (e.g., 50 µm or less) may be determined from the viewpoint of handling of the cleaning substrate 10a and driving of the substrate processing device described below, and may be changed depending on the total thickness of the cleaning substrate 10a.

The adhesive layer 12 may be disposed on one surface of the electrostatic control layer 11. The adhesive layer 12 may include a material that allows repeated adhesion and peeling without an external heat or solvent treatment. For example, the adhesive layer 12 may include a pressure sensitive adhesive (PSA). The adhesive layer 12 may be combined with the electrostatic control layer 11 to attach contaminant particles having weakened electrostatic attraction and remove the same from the surface of the chuck. The adhesive layer 12 may include, for example, a rubber-based, acrylic-based, silicone-based, or polyvinyl ether-based adhesive. The adhesive layer 12 may further include an additive that can provide improved adhesive force, particle selectivity, antistatic function, and the like.

A thickness (d2) of the adhesive layer 12 may be in a range of 5 µm or more, for example, in a range of 5 µm to 20 µm, in a range of 5 µm to 15 µm, or in a range of 5 µm to 10 µm. When the thickness (d2) of the adhesive layer 12 is less than 5 µm, an effect of removing contaminant particles may be reduced. An upper limit of the thickness (d2) of the adhesive layer 12 may be determined at a level at which an effect of controlling electrostatic attraction of the electrostatic control layer 11 is not reduced. When the thickness (d2) of the adhesive layer 12 exceeds 20 µm, the possibility of reverse contamination of the surface of the chuck may increase. According to an example embodiment, because the electrostatic attraction of the contaminant particles is weakened or removed by the electrostatic control layer 11, the contaminant particles may be effectively removed without excessively increasing the adhesive force, thickness, or the like, of the adhesive layer 12.

The base film 13 may be disposed on the other surface of the electrostatic control layer 11 opposite to the adhesive layer 12. The base film 13 may include a resin film including any one or any combination of, for example, polyolefin (PO), polyethylene terephthalate (PET), polyethylene naphthalate (PEN), polyether ether ketone (PEEK), polyimide (PI), polyvinyl chloride (PVC), or ethylene vinyl acetate (EVA).

A thickness (d3) of the base film 13 may be in a range of 50 µm to 100 µm. When the thickness (d3) of the base film 13 is less than 50 µm, the physical properties necessary for supporting the electrostatic control layer 11 and the adhesive layer 12 may be insufficient. An upper limit of the thickness (d3) of the base film 13 (e.g., 100 µm or less) may be determined from the viewpoint of handling the cleaning substrate 10a and driving the substrate processing device described below, and may be changed depending on the total thickness of the cleaning substrate 10a.

Referring to FIG. 1B, a cleaning substrate 10b of an example embodiment may not include a base film 13. The cleaning substrate 10b may include an electrostatic control layer 11 and an adhesive layer 12 attached to one surface of the electrostatic control layer 11.

The thickness (d1) of the electrostatic control layer 11 may be in a range of 50 µm or more, for example, in a range of 50 µm to 200 µm, 55 µm to 200 µm, 60 µm to 200 µm, 65 µm to 200 µm, or the like. When the thickness (d1) of the electrostatic control layer 11 is less than 50 µm, the physical properties required as a support layer may be insufficient. An upper limit (e.g., 200 µm or less) of the thickness (d1) of the electrostatic control layer 11 may be determined from the viewpoint of handling of the cleaning substrate (10a) and driving the substrate processing device described below, and may be changed depending on the total thickness of the cleaning substrate 10a. Because the electrostatic control layer 11 has a more flexible characteristic than the base film 13, an upper limit of the total thickness of the cleaning substrate 10b may be increased.

A thickness (d2) of the adhesive layer 12 may be in a range of 5 µm or more, for example, in a range of 5 µm to 20 µm, in a range of 5 µm to 15 µm, or in a range of 5 µm to 10 µm, or the like. When the thickness (d2) of the adhesive layer 12 is less than 5 µm, an effect of removing contaminant particles may be reduced. An upper limit of the thickness (d2) of the adhesive layer 12 may be determined at a level at which an effect of controlling electrostatic attraction of the electrostatic control layer 11 is not reduced. When the thickness (d2) of the adhesive layer 12 exceeds 20 µm, the possibility of reverse contamination of the surface of the chuck may increase. According to an example embodiment, because the electrostatic attraction of the contaminant particles is weakened or removed by the electrostatic control layer 11, the contaminant particles may be effectively removed without excessively increasing the adhesive force, thickness, and the like, of the adhesive layer 12.

FIGS. 2A and 2B are views illustrating an electrostatic control layer (11, 11’) according to example embodiments.

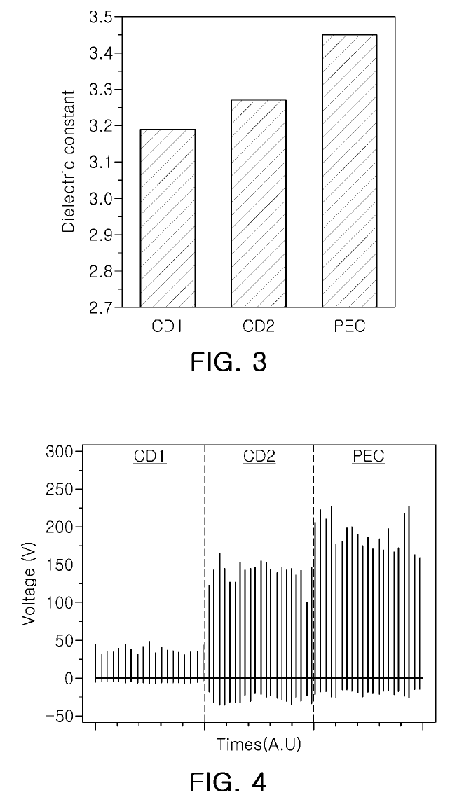

FIGS. 3 and 4 are graphs illustrating a dielectric constant and self-generated voltage of an electrostatic control layer of an example embodiment.

FIG. 3 illustrates a dielectric constant of a first composite dielectric specimen CD1, a second composite dielectric specimen CD2, and a preliminary electrostatic dielectric specimen PEC. . The first composite dielectric specimen CD1 does not include pores PR or conductive particles 11b. The second composite dielectric specimen CD2 includes pores PR but does not include conductive particles 11b. The preliminary electrostatic dielectric specimen PEC includes both pores PR and conductive particles 11b.

FIG. 4 illustrates voltage characteristics of each of the first composite dielectric specimen CD1, the second composite dielectric specimen CD2, and the preliminary electrostatic control layer PEC according to the number of external stimuli.

Referring to FIG. 2A, an electrostatic control layer 11 of an example embodiment may be configured to have TENG characteristics. The electrostatic control layer 11 may include a composite dielectric layer 11a and conductive particles 11b. The composite dielectric layer 11a may include an organic polymer M1 and an inorganic particle M2. The electrostatic control layer 11 according to an example embodiment may implement TENG characteristics and improve dust collection characteristics by including the composite dielectric layer 11a and conductive particles 11b.

The organic polymer M1 may include a material having low electron affinity and high flexibility. For example, the organic polymer M1 may function as a tribo-surface that gains or loses charge during contact and separation with a friction target. The organic polymer M1 may include any one or any combination of polydimethylsiloxane (PDMS), polymethyl methacrylate (PMMA), polyvinylidene fluoride (PVDF), polyimide (PI), polyurethane (PU), polyethylene terephthalate (PET), polycarbonate (PC), epoxy resin, or polyamide (PA).

The inorganic particles M2 may be dispersed within the organic polymer M1. The inorganic particles M2 may include a piezoelectric material. The inorganic particles M2 may generate a potential difference by inducing charge rearrangement within a crystal lattice by external stimuli such as friction, and may assist or amplify charge generation due to friction. The inorganic particles M2 may be dispersed within an organic polymer to form a complex dielectric structure, and improve electrostatic sensitivity to external force. The inorganic particles M2 may include a titanate-based material such as barium titanate (BTO, BaTiO₃), strontium titanate (SrTiO₃), lead titanate (PbTiO₃), lead zirconate titanate (PZT, Pb(Zr,Ti)O₃), or the like. In some example embodiments, the inorganic particles M2 may include a non-titanate material (e.g., niobate-based, tantalate-based, etc.) such as potassium niobate (KNbO₃), sodium niobate (NaNbO₃), potassium sodium niobate (KNN, K₀.₅Na₀.₅NbO₃), lithium niobate (LNO, LiNbO₃), lithium tantalate (LTO, LiTaO₃), zinc oxide (ZnO), molybdenum disulfide (MoS₂), gallium nitride (GaN), aluminum nitride (AlN), or the like. The inorganic particles M2 may include any one or any combination of the titanate-based piezoelectric material or the non-titanate-based piezoelectric material described above.

The conductive particles 11b may be disposed inside or on a surface of the composite dielectric layer 11a to collect charges induced by friction or to improve output characteristics thereof by facilitating the movement of an interface potential. The conductive particles 11b may control the distribution of an electrostatic field based on high electrical conductivity and interface characteristics of the conductive particles 11b. The conductive particles 11b may include, for example, any one or any combination of silver nanoparticles (Ag NP), gold nanoparticles (Au NP), copper nanoparticles (Cu NP), reduced graphene oxide (rGO), graphene nanoplatelets, carbon nanotubes (CNT), or carbon nanofibers (CNF).

For example, the cleaning substrate 10a may be formed by mixing a BTO and gold nanoparticle suspension into a polymer matrix including PDMS and then curing the same. Each of the BTO and gold nanoparticles may be added in an amount of 0.1 wt% to 5 wt% relative to the polymer matrix. The cleaning substrate 10a including BTO and gold nanoparticles may have improved dielectric properties and self-generated voltage properties. When BTO or gold nanoparticles are added in an amount less than 0.1 wt%, the electrostatic attraction control effect may not be sufficient. When BTO or gold nanoparticles are added in an amount exceeding 5 wt%, Electrostatic Discharge (ESD) may occur within the equipment.

Referring to FIG. 2B, the electrostatic control layer 11’ of a modified example may include pores PR in which conductive particles 11b are accommodated. For example, the cleaning substrate 10b may be formed using a foaming agent. First, a foaming agent such as BTO and sucrose may be mixed into a polymer matrix including PDMS, and then casting and degassing may be performed to form a preliminary substrate including pores PR. Next, sucrose in the preliminary substrate may be dissolved, and a gold nanoparticle suspension may be injected so that the gold nanoparticles may be accommodated in the pores PR.

Referring to FIGS. 3 and 4, a first composite dielectric specimen CD1, a second composite dielectric specimen CD2, and a preliminary electrostatic control layer (PEC) have sequentially improved dielectric properties and self-generated voltage properties. Therefore, the dielectric properties and self-generated voltage properties of the electrostatic control layer (11, 11’) of an example embodiment may be predicted. The electrostatic control layer (11, 11’) includes a piezoelectric material M2 and conductive nanoparticles 11b, so that a dielectric constant and self-generated voltage may be significantly increased.

As described above, the electrostatic control layer (11, 11’) may have improved dielectric properties and self-generated voltage properties by having a material composition including a composite dielectric layer 11a and conductive nanoparticles 11b. The electrostatic control layer (11, 11’) may weaken or eliminate the electrostatic attraction between the chuck and the contaminant particles attached to the surface of the chuck, by forming a potential using mechanical friction or vibration energy from the outside without an external power source.

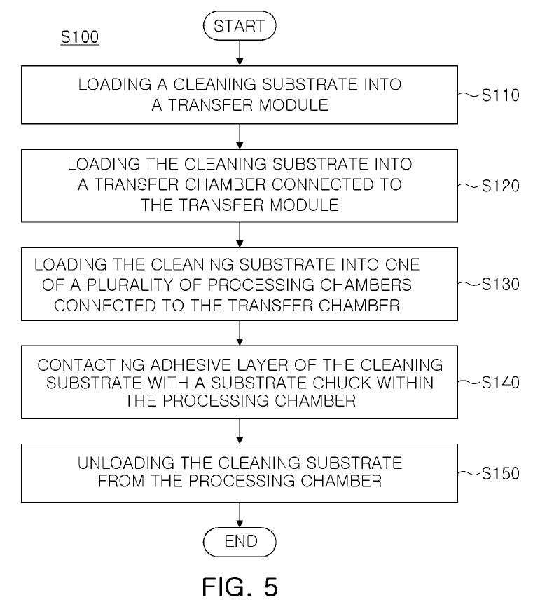

FIG. 5 is a flowchart illustrating a method for cleaning a substrate chuck (S100) according to an example embodiment.

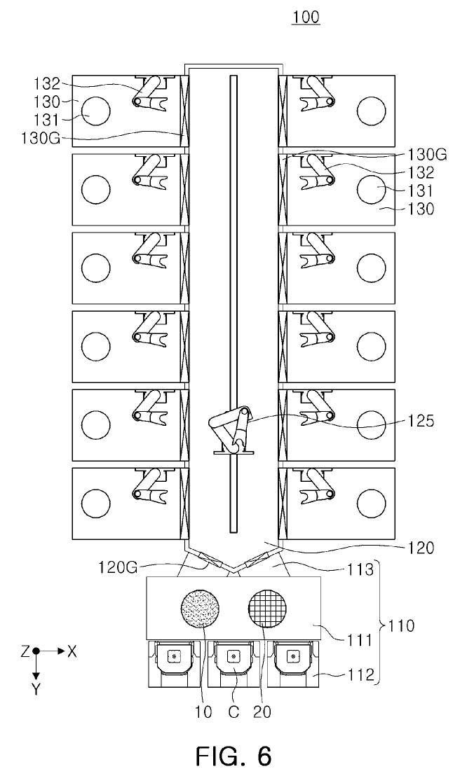

FIGS. 6-9 are views illustrating a process according to the method for cleaning a substrate chuck (S100) of FIG. 5. FIGS. 6-9 illustrate an example substrate processing device 100 on which the cleaning method (S100) of an example embodiment is performed.

Referring to FIG. 5, the method for cleaning a substrate chuck (S100) of the substrate chuck of an example embodiment may include: loading a cleaning substrate into a transfer module (i.e., transfer apparatus) (S110); loading the cleaning substrate into a transfer chamber connected to the transfer module (S120); loading the cleaning substrate into one of a plurality of processing chambers connected to the transfer chamber, each of the plurality of processing chambers including a substrate chuck (S130); contacting the adhesive layer of the cleaning substrate with the substrate chuck (S140); and unloading the cleaning substrate from the processing chamber (S150). Hereinafter, the substrate processing device 100 in which a method for cleaning a substrate chuck (S100) is performed is illustrated as an example, the method for cleaning a substrate chuck (S100) may also be performed in a device having a different shape and configuration than those illustrated in FIGS. 6-9.

Referring to FIG. 6, a cleaning substrate 10 may be loaded into a transfer module 110 (or referred to as a ‘substrate transfer module’) of a substrate processing device 100. In some example embodiments, both a cleaning substrate 10 and a device substrate 20 may be loaded into the substrate transfer module 110. The substrate processing device 100 may be driven according to a recipe based on a code of a substrate carrier (C) or a slot number inside the substrate carrier (C). For example, when the substrate carrier (C) includes only a cleaning substrate 10, a substrate chuck cleaning process may be performed by recognizing a unique code of the substrate carrier (C) and operate according to a recipe associated with the recognized code. When the substrate carrier (C) includes both the cleaning substrate 10 and the device substrate 20, the cleaning substrate 10 and the device substrate 20 are recognized by slot numbers, and a substrate chuck cleaning process or a device forming process may be performed in each processing chamber according to recipes associated with the recognized slot numbers. The substrate carrier (C) may include a Front Opening Unified Pod (FOUP) or Mechanical Arm-Compatible Cassette (MAC) accommodating a semiconductor wafer. The cleaning substrate 10 may be understood as a wafer structure having a material composition described with reference to FIGS. 1-4. The device substrate 20 may be understood as a semiconductor wafer on which a designed device circuit is formed.

The substrate processing device 100 may include a substrate transfer module 110. The substrate processing device 100 may include one or more processors and one or more memories storing instructions, which when executed by the one or more processors, control the substrate processing device 100 to perform operations described herein. The substrate transfer module 110 may be configured to unload and align a substrate to be provided to the process, for example, a cleaning substrate 10 or a device substrate 20, from a substrate carrier (C) to transfer the substrate to a transfer chamber 120. In addition, the substrate transfer module 110 may be configured to receive a cleaning substrate 10 or a device substrate 20 having completed a process from the transfer chamber 120 and temporarily store the same or be loaded into the substrate carrier (C). For example, the substrate transfer module (or substrate transfer device) 110 may include a chamber 111, a load port 112, and a load lock 113.

The chamber 111 may have an internal space in which configurations for loading and unloading a cleaning substrate 10 or a device substrate 20 are disposed. The internal space of the chamber 111 may provide a movement path in a vertical direction and/or a horizontal direction of the cleaning substrate 10 or the device substrate 20 unloaded from the substrate carrier (C). The chamber 111 may include a substrate alignment device, a buffer (e.g., buffing device), a robot arm, or the like, disposed in the internal space thereof.

The load port 112 may be configured to support and move the substrate carrier (C) to be coupled to the chamber 111. The load port 112 may be configured to move or rotate the substrate carrier (C) in the horizontal direction and the vertical direction to couple the substrate carrier (C) to the chamber 111. A door of the substrate carrier (C) may be coupled to a gate on one side of the chamber 111 and be opened and closed.

The load lock 113 may be configured to control pressure inside the load lock 113 where a cleaning substrate 10 or a device substrate 20 is accommodated. The load lock 113 may include one or more vacuum pumps and one or more pressure sensors. For example, when the cleaning substrate 10 or the device substrate 20 is transferred to the transfer chamber 120, the pressure inside the load lock 113 may be controlled to have substantially the same vacuum pressure as the transfer chamber 120. Alternatively, when the cleaning substrate 10 or the device substrate 20 is transferred to the transfer chamber 120, the pressure inside the load lock 113 may be controlled to have substantially the same atmospheric pressure as the transfer chamber 120. The load lock 113 may also function as a cooling chamber cooling the temporarily stored cleaning substrate 10 or device substrate 20. In this regard, the load lock 113 may also include a cooling device.

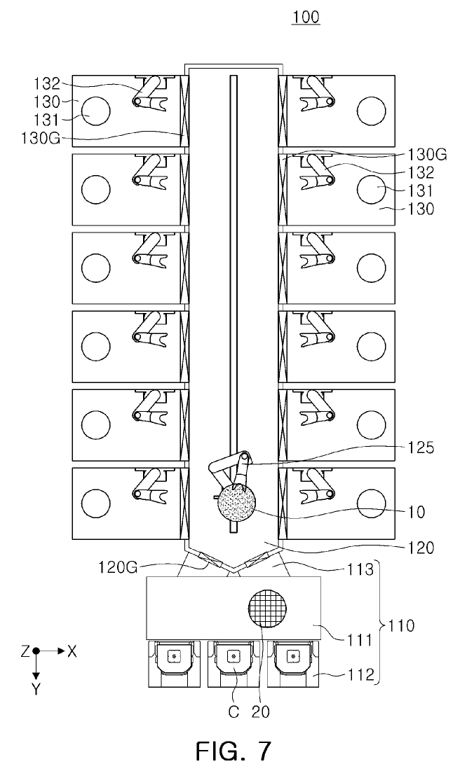

Referring to FIG. 7, a cleaning substrate 10 may be loaded into a transfer chamber 120 connected to the transfer module 110. The substrate processing device 100 may include a transfer chamber 120.

The transfer chamber 120 may be configured to transfer a cleaning substrate 10 or a device substrate 20 between the substrate transfer module 110 and a processing chamber 130. The transfer chamber 120 may be spatially connected to the substrate transfer module 110 (or load lock 113) and the processing chamber 130. For example, the transfer chamber 120 may be configured to transfer a cleaning substrate 10 or a device substrate 20 received from the substrate transfer module 110 to the processing chamber 130, or to transfer a cleaning substrate 10 or a device substrate 20 received from the processing chamber 130 to the substrate transfer module 110.

A gate 120G which allows or blocks an entry and exit of the cleaning substrate 10 or the device substrate 20 may be disposed between the transfer chamber 120 and the substrate transfer module 110 (or load lock 113). In addition, a gate 130G which allows or blocks the entry and exit of the cleaning substrate 10 or the device substrate 20 may be disposed between the transfer chamber 120 and the processing chamber 130. When the gate 130G between the transfer chamber 120 and the processing chamber 130 is opened, a transfer arm 125 configured to load or unload the cleaning substrate 10 or the device substrate 20 may be disposed inside the transfer chamber 120. Pressure inside the transfer chamber 120 may be controlled to have substantially the same vacuum pressure or atmospheric pressure as the processing chamber 130.

The transfer arm 125 may be disposed inside the transfer chamber 120, and configured to unload the cleaning substrate 10 or the device substrate 20 from the substrate transfer module 110 (or load lock 113) and load it into one of the plurality of processing chambers 130. For example, the transfer arm 125 may be configured to move in a horizontal direction inside the transfer chamber 120, and unload a cleaning substrate 10 or a device substrate 20 from the substrate transfer module 110 (or load lock 113) and load it into the processing chamber 130, or unload a cleaning substrate 10 or a device substrate 20 of which the process has been completed from the processing chamber 130 and load it into the substrate transfer module 110 (or load lock 113). The transfer arm 125 may be a robot arm configured to handle a cleaning substrate 10 or a device substrate 20 under vacuum or atmospheric pressure.

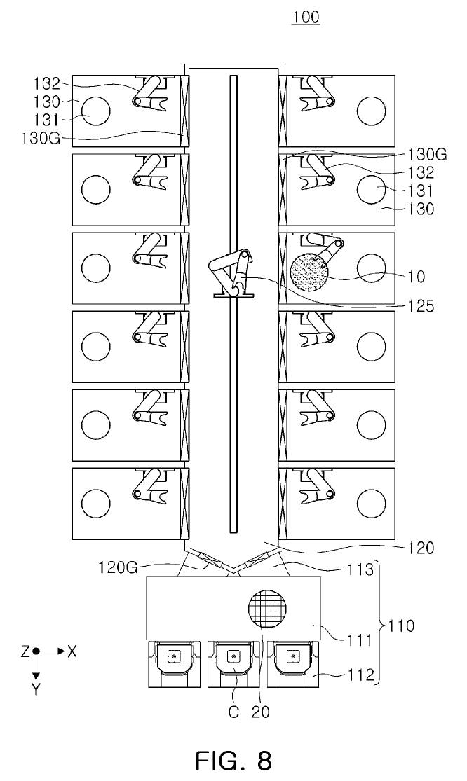

Referring to FIG. 8, a cleaning substrate 10 may be loaded into a processing chamber 130. The substrate processing device 100 may include at least one processing chamber 130. A gate 130G which allows or blocks an entry and exit of a cleaning substrate 10 or a device substrate 20 may be disposed between the processing chamber 130 and the transfer chamber 120. Pressure inside the processing chamber 130 may be controlled to have substantially the same vacuum pressure or atmospheric pressure as that of the transfer chamber 120. When the substrate processing device 100 includes a plurality of processing chambers 130, a substrate chuck cleaning process using the cleaning substrate 10 may be performed alone in the plurality of processing chambers 130, or a device forming process for the device substrate 20 may be performed alone in the plurality of processing chambers 130, or the substrate chuck cleaning process and the device forming process may be performed, respectively, in the plurality of processing chambers 130. For example, the cleaning substrate 10 may be loaded into one of the plurality of processing chambers 130 connected to the transfer chamber 120.

The processing chamber 130 may be a device for processing a cleaning substrate 10 or a device substrate 20 received from the transfer chamber 120. The processing chamber 130 may include, for example, a deposition chamber such as a chemical vapor deposition (CVD) chamber, a physical vapor deposition (PVD) chamber, and an atomic layer deposition (ALD) chamber, an oxidation chamber, a heat treatment chamber, a cleaning chamber, an etching chamber, or the like. The processing chamber 130 may include components for processing a cleaning substrate 10 or a device substrate 20, such as a substrate chuck 131, a handler 132, or the like. The substrate chuck 131 may include an electrostatic chuck or a vacuum chuck configured to support and fix the device substrate 20. The handler 132 may be a robot arm configured to load or unload a cleaning substrate 10 or a device substrate 20, when a gate 130G configured to handle the cleaning substrate 10 and the device substrate 20 inside the processing chamber 130 is opened, or may be a dynamic structure such as a clamp.

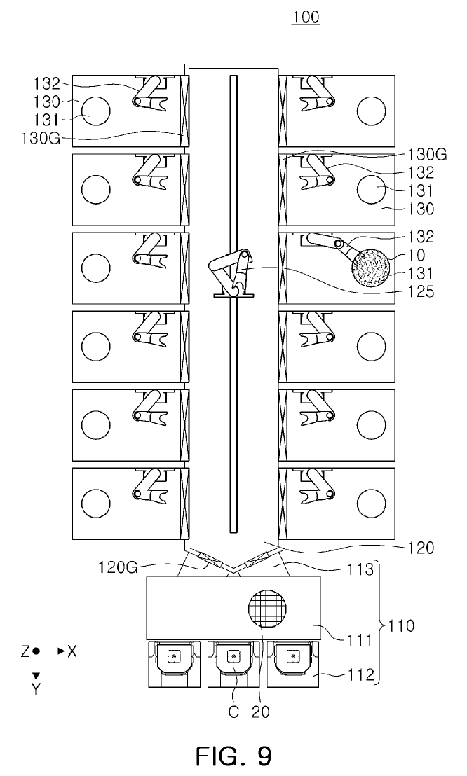

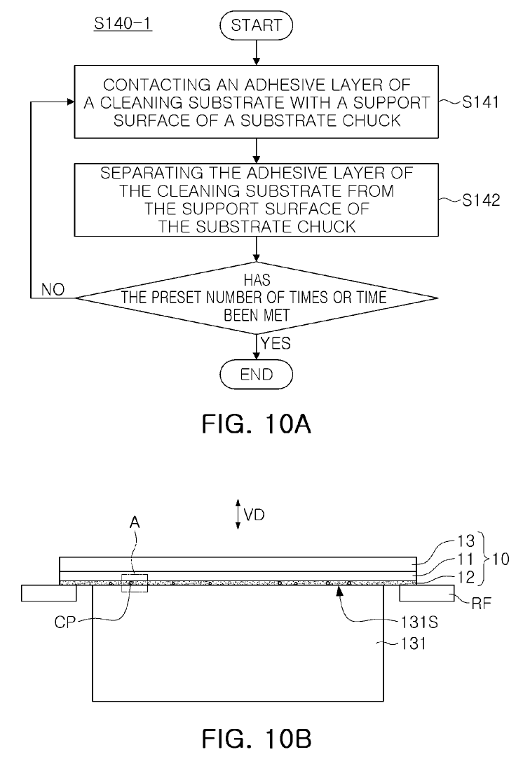

Referring to FIG. 9, the cleaning substrate 10 may make contact with the substrate chuck 131 one or more times. The cleaning substrate 10 may reciprocate in at least one of a vertical direction or a horizontal direction on the substrate chuck 131 by the handler 132. This will be described in more detail with reference to FIGS. 10A and 10B. In a cleaning process of the substrate chuck 131 using the cleaning substrate 10, the substrate chuck 131 may not operate to secure the cleaning substrate 10. For example, in the cleaning process of the substrate chuck 131, the cleaning substrate 10 may not be fixed by the electrostatic attraction or vacuum pressure of the substrate chuck 131. Thereafter, the cleaning substrate 10 may be unloaded from the processing chamber 130. As described above, according to an example embodiment, the cleaning process of the substrate chuck may be performed by a process flow of the substrate processing device 100. Accordingly, the cleanliness of the substrate chuck 131 may be maintained without shutting down the substrate processing device 100 or stopping the process flow for preventive maintenance (PM), so that various defects due to contaminants on the surface of the substrate chuck 131 may be prevented and a substrate processing yield may be improved.

FIG. 10A is a flowchart illustrating a method for removing contaminant particles from a substrate chuck according to an example embodiment, and FIG. 10B is a view illustrating the process of FIG. 10A.

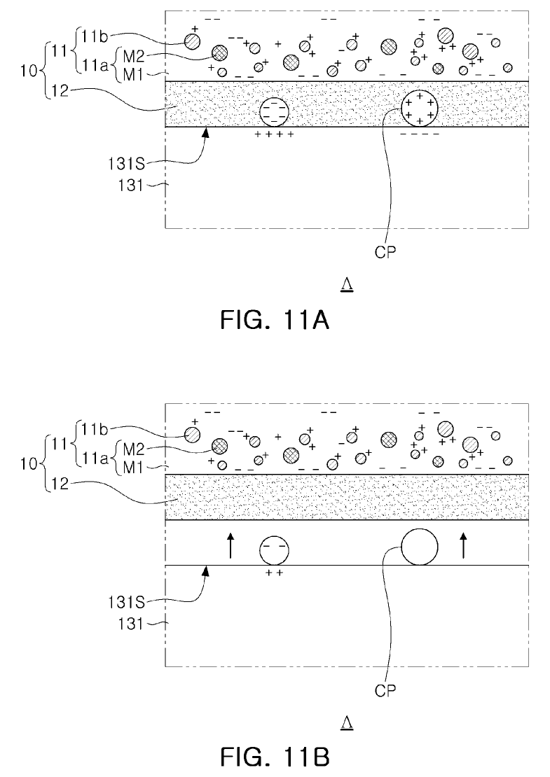

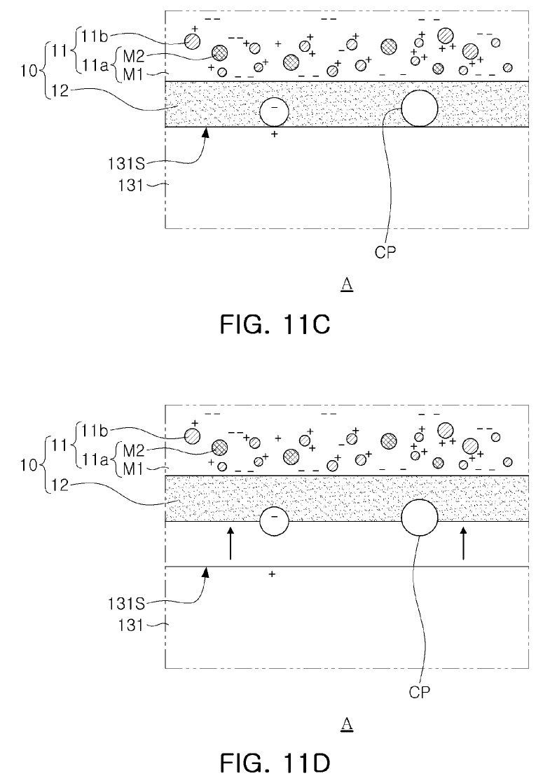

FIGS. 11A, 11B, 11C, and 11D are views illustrating the process of removing contaminant particles according to FIGS. 10A and 10B. FIGS. 11A, 11B, 11C, and 11D illustrate region ‘A’ of FIG. 10B.

Referring to FIGS. 10A and 10B, in an example embodiment, the operation of contacting a cleaning substrate 10 with a substrate chuck 131 (S140-1) may include contacting an adhesive layer 12 of the cleaning substrate 10 with a support surface 131S of the substrate chuck 131 one or more times. For example, the cleaning substrate 10 may reciprocate in a vertical direction (VD) so that the adhesive layer 12 having a ring frame RF attached thereto is in contact with the support surface 131S of the substrate chuck 131. The substrate chuck 131 may not be operated to secure the cleaning substrate 10, and electrostatic attraction or vacuum pressure due to the substrate chuck 131 may not act between the cleaning substrate 10 and the support surface 131S of the substrate chuck 131. The cleaning substrate 10 may include an electrostatic control layer 11, an adhesive layer 12, and a base film 13. The control layer 11, the adhesive layer 12, and the base film 13 may be understood to have the same or similar characteristics as those described with reference to FIGS. 1A-4.

For example, the operation of contacting the cleaning substrate 10 with the substrate chuck 131 (S140-1) may include a first operation (S141) of contacting the adhesive layer 12 with the support surface 131S of the substrate chuck 131, and a second operation (S142) of separating the adhesive layer 12 from the support surface 131S of the substrate chuck 131. The first operation (S141) and the second operation (S142) may be performed repeatedly until a preset number of times or time is met. For example, the first operation (S141) and the second operation (S142) may be sequentially repeated two or more times.

Referring to FIG. 11A, the adhesive layer 12 of the cleaning substrate 10 may be in direct contact with the support surface 131S of the substrate chuck 131 (S141). In this case, a self-generated voltage may be generated within the electrostatic control layer 11 located opposite the support surface (131S). An organic polymer M1 and conductive nanoparticles 11b included in the electrostatic control layer 11 may amplify a potential difference generated from inorganic particles M2 including a piezoelectric material. Contaminant particles CP may exist on the substrate chuck 131. Contamination particles CP may be + or - charged and attached to the support surface 131S of the substrate chuck 131 by electrostatic attraction.

Referring to FIG. 11B, the cleaning substrate 10 may be separated from the support surface 131S of the substrate chuck 131 (S142). Contamination particles CP may still be attached to the substrate chuck 131 by electrostatic attraction. However, due to the potential difference and electric field generated within the electrostatic control layer 11, electrostatic charges charged to the contaminant particles CP may be disturbed, a change in an electric field and electric repulsion may be induced, so that the electrostatic attraction between the contaminant particles CP and the substrate chuck 131 may be weakened or removed.

Referring to FIG. 11C, the adhesive layer 12 of the cleaning substrate 10 may be in direct contact with the support surface 131S of the substrate chuck 131 (S141). In this case, a portion of the potential difference formed previously may exist in the electrostatic control layer 11, or the potential difference may be re-generated by contact with the substrate chuck 131. The electrostatic attraction between the contaminant particles CP and the substrate chuck 131 may be weakened or removed.

Referring to FIG. 11D, the cleaning substrate 10 may be separated again from the support surface 131S of the substrate chuck 131 (S142). Contaminant particles CP of which electrostatic attraction with the substrate chuck 131 is weaker than adhesive force of the adhesive layer 12 may be attached to the adhesive layer 12 and removed from the substrate chuck 131. As described above, according to an example embodiment, by the cleaning substrate 10 including the electrostatic control layer 11, the electrostatic adhesion strength of the contaminant particles may be reduced and the detachment of the contaminant particles may be induced, so that the contaminant particles CP of the support surface 131S of the substrate chuck 131 may be effectively removed.

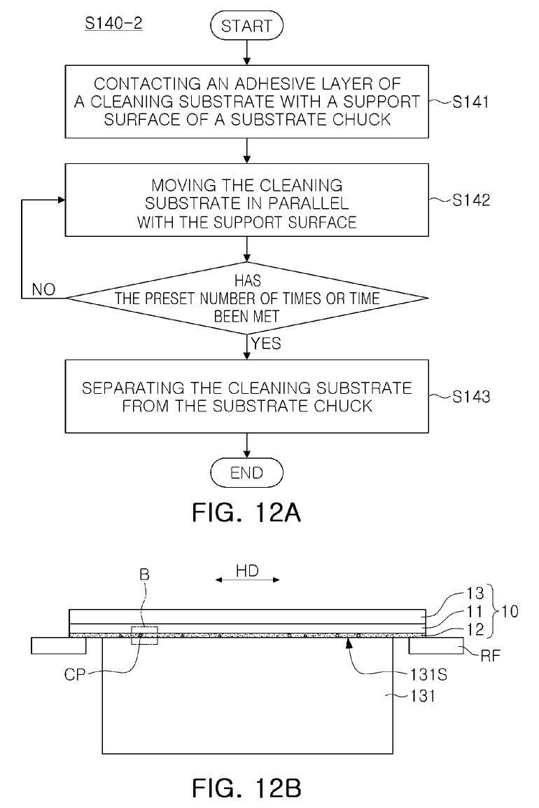

FIG. 12A is a flowchart illustrating a method for removing contaminant particles from a substrate chuck (S140-2) according to an example embodiment, and FIG. 12B is a view illustrating the process of FIG. 12A.

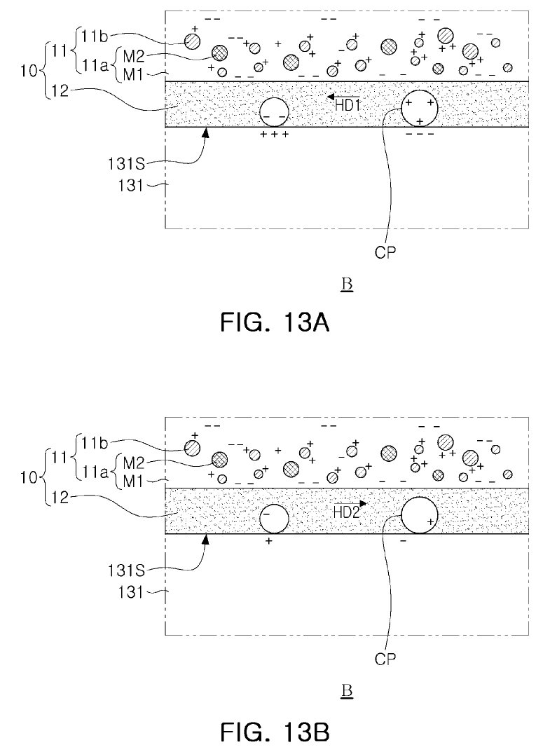

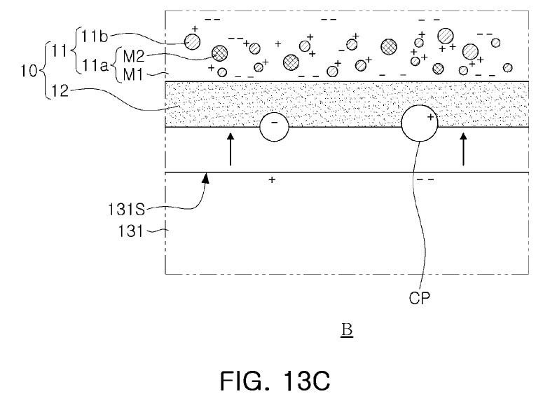

FIGS. 13A, 13B and 13C are views illustrating the process of removing contaminant particles according to FIGS. 12A and 12B. FIGS. 13A, 13B, and 13C illustrate ‘B’ region of FIG. 12B.

Referring to FIGS. 12A and 12B, in an example embodiment, the operation of contacting the cleaning substrate 10 with a substrate chuck 131 (S140-2) may include contacting an adhesive layer 12 of the cleaning substrate 10 with a support surface 131S of the substrate chuck 131 one or more times. For example, the cleaning substrate 10 may reciprocate in a horizontal direction (HD) so that the adhesive layer 12 having a ring frame RF attached thereto is in contact with the support surface 131S of the substrate chuck 131. The substrate chuck 131 may not be operated, and electrostatic attraction or vacuum pressure due to the substrate chuck 131 may not act between the cleaning substrate 10 and the support surface 131S of the substrate chuck 131. The cleaning substrate 10 may include an electrostatic control layer 11, an adhesive layer 12, and a base film 13. The control layer 11, the adhesive layer 12, and the base film 13 may be understood to have the same or similar characteristics as those described with reference to FIGS. 1A-4.

For example, the operation of contacting the cleaning substrate 10 with the substrate chuck 131 (S140-2) may include a first operation (S141) of contacting the adhesive layer 12 with the support surface 131S of the substrate chuck 131, and a second operation (S142) of moving the adhesive layer 12 in parallel with the support surface 131S while the adhesive layer 12 is in contact with the support surface 131S. The second operation (S142) may be performed repeatedly until the preset number of times or time is met. For example, the second operation (S142) may be repeated two or more times.

Referring to FIG. 13A, the cleaning substrate 10 may be moved in a first direction HD1 while the adhesive layer 12 is in direct contact with the support surface 131S of the substrate chuck 131 (S142). The first direction HD1 may be parallel to the support surface 131S. In this case, a self-generated voltage may be generated within the electrostatic control layer 11 located opposite the support surface 131S. An organic polymer M1 and conductive nanoparticles 11b included in the electrostatic control layer 11 may amplify a potential difference generated from inorganic particles M2 including a piezoelectric material. Contaminant particles CP may exist on the substrate chuck 131. The contamination particles CP may be + or - charged and attached to the support surface 131S of the substrate chuck 131 by electrostatic attraction.

Referring to FIG. 13B, the cleaning substrate 10 may be moved in a second direction HD2 while the adhesive layer 12 is in direct contact with the support surface 131S of the substrate chuck 131 (S142). The second direction HD2 may be parallel to the support surface 131S and may cross the first direction HD1. The second direction HD2 may be an opposite direction to the first direction HD1, but example embodiments are not limited thereto. That is, the first direction HD1 and the second direction HD2 may be directions that can induce friction between the adhesive layer 12 and the support surface 131S. The contaminant particles CP may still be attached to the substrate chuck 131 by electrostatic attraction. However, due to a potential difference and an electric field generated within the electrostatic control layer 11, electrostatic charges charged to the contaminant particles CP may be disturbed, and a change in an electric field, electric repulsion, and the like, may be induced, so that the electrostatic attraction between the contaminant particles CP and the substrate chuck 131 may be weakened or removed.

Referring to FIG. 13C, the cleaning substrate 10 may be separated again from the support surface 131S of the substrate chuck 131 (S143). Contaminant particles CP of which electrostatic attraction with the substrate chuck 131 is weaker than adhesive force of the adhesive layer 12 may be attached to the adhesive layer 12 and removed from the substrate chuck 131. As described above, according to an example embodiment, by the cleaning substrate 10 including the electrostatic control layer 11, the electrostatic adhesion strength of the contaminant particles may be reduced and the detachment of the contaminant particles may be induced, so that the contaminant particles CP of the support surface 131S of the substrate chuck 131 may be effectively removed.

According to example embodiments, a method for cleaning a substrate chuck having improved dust collection characteristics may be provided by introducing a cleaning substrate for controlling electrostatic attraction of contaminant particles.

According to an aspect of an example embodiment, an apparatus includes: one or more memories storing instructions; and one or more processors configured to execute the instructions to control the apparatus to load a cleaning substrate into a transfer apparatus, the cleaning substrate including an electrostatic control layer and an adhesive layer disposed on one surface of the electrostatic control layer; load the cleaning substrate from the transfer module into a transfer chamber connected to the transfer apparatus; load the cleaning substrate from the transfer chamber into one of a plurality of processing chambers connected to the transfer chamber, a processing chamber of the plurality of processing chambers including the substrate chuck; control the substrate chuck to contact the adhesive layer of the cleaning substrate; and unload the cleaning substrate from the processing chamber.

According to an aspect of an example embodiment, a cleaning substrate includes an electrostatic control layer and an adhesive layer disposed on one surface of the electrostatic control layer, wherein the electrostatic control layer includes a composite dielectric layer and conductive particles, wherein the composite dielectric layer includes an organic polymer and an inorganic particle.

The organic polymer provides a cleaning substrate including any one or any combination of polydimethylsiloxane (PDMS), polymethyl methacrylate (PMMA), polyvinylidene fluoride (PVDF), polyimide (PI), polyurethane (PU), polyethylene terephthalate (PET), polycarbonate (PC), epoxy resin, or polyamide (PA).

The inorganic particle provides a cleaning substrate including any one or any combination of barium titanate (BTO, BaTiO₃), strontium titanate (SrTiO₃), lead titanate (PbTiO₃), lead zirconate titanate (PZT, Pb(Zr,Ti)O₃), potassium niobate (KNbO₃), sodium niobate (NaNbO₃), potassium sodium niobate (KNN, K₀₋₅Na₀₋₅NbO₃), lithium niobate (LNO, LiNbO₃), lithium tantalate (LTO, LiTaO₃), zinc oxide (ZnO), molybdenum disulfide (MoS₂), gallium nitride (GaN), or aluminum nitride (AlN).

The conductive particles provide a cleaning substrate including any one or any combination of silver nanoparticles (Ag NP), gold nanoparticles (Au NP), copper nanoparticles (Cu NP), reduced graphene oxide (rGO), graphene nanoplatelets, carbon nanotubes (CNT), or carbon nanofibers (CNF).

While aspects of example embodiments have been illustrated and described, it will be apparent to those skilled in the art that modifications and variations could be made without departing from the scope of the present inventive concept as defined by the appended claims.

What is claimed is:

1. A method for cleaning a substrate chuck, comprising:
loading a cleaning substrate into a transfer module, the cleaning substrate including an electrostatic control layer and an adhesive layer disposed on one surface of the electrostatic control layer;
loading the cleaning substrate from the transfer module into a transfer chamber connected to the transfer module;
loading the cleaning substrate from the transfer chamber into one of a plurality of processing chambers connected to the transfer chamber, a processing chamber of the plurality of processing chambers including the substrate chuck;
controlling the cleaning substrate so that the adhesive layer contacts the substrate chuck; and
unloading the cleaning substrate from the processing chamber.

2. The method for cleaning a substrate chuck of claim 1, wherein the electrostatic control layer includes a composite dielectric layer and conductive particles.

3. The method for cleaning a substrate chuck of claim 2, wherein the composite dielectric layer includes an organic polymer and inorganic particles.

4. The method for cleaning a substrate chuck of claim 3, wherein the organic polymer includes any one or any combination of polydimethylsiloxane (PDMS), polymethyl methacrylate (PMMA), polyvinylidene fluoride (PVDF), polyimide (PI), polyurethane (PU), polyethylene terephthalate (PET), polycarbonate (PC), epoxy resin, or polyamide (PA).

5. The method for cleaning a substrate chuck of claim 3, wherein the inorganic particles include any one or any combination of barium titanate (BTO, BaTiO₃), strontium titanate (SrTiO₃), lead titanate (PbTiO₃), lead zirconate titanate (PZT, Pb(Zr,Ti)O₃), potassium niobate (KNbO₃), sodium niobate (NaNbO₃), potassium sodium niobate (KNN, K₀₋₅Na₀₋₅NbO₃), lithium niobate (LNO, LiNbO₃), lithium tantalate (LTO, LiTaO₃), zinc oxide (ZnO), molybdenum disulfide (MoS₂), gallium nitride (GaN), or aluminum nitride (AlN).

6. The method for cleaning a substrate chuck of claim 2, wherein the conductive particles include any one or any combination of silver nanoparticles (Ag NP), gold nanoparticles (Au NP), copper nanoparticles (Cu NP), reduced graphene oxide (rGO), graphene nanoplatelets, carbon nanotubes (CNT), or carbon nanofibers (CNF).

7. The method for cleaning a substrate chuck of claim 1, wherein the controlling the cleaning substrate comprises:
a first operation of contacting the adhesive layer with a support surface of the substrate chuck, and
a second operation of separating the adhesive layer from the support surface of the substrate chuck, and
wherein the first operation and the second operation are sequentially and repeated two or more times.

8. The method for cleaning a substrate chuck of claim 1, wherein the controlling the cleaning substrate comprises:
a first operation of contacting the adhesive layer with a support surface of the substrate chuck, and
a second operation of moving the adhesive layer in parallel with the support surface, while the adhesive layer is in contact with the support surface, and
wherein the second operation is repeated two or more times.

9. The method for cleaning a substrate chuck of claim 1, wherein the cleaning substrate further comprises a base film disposed on another surface of the electrostatic control layer, opposite to the adhesive layer.

10. The method for cleaning a substrate chuck of claim 9, wherein the base film comprises any one or any combination of polyolefin (PO), polyethylene terephthalate (PET), polyethylene naphthalate (PEN), polyether ether ketone (PEEK), polyimide (PI), polyvinyl chloride (PVC), or ethylene vinyl acetate (EVA).

11. The method for cleaning a substrate chuck of claim 9, wherein a thickness of the base film is in a range of 50 µm to 100 µm.

12. The method for cleaning a substrate chuck of claim 9, wherein a thickness of the adhesive layer is in a range of 5 µm to 20 µm, and
wherein a thickness of the electrostatic control layer is in a range of 10 µm to 50 µm.

13. The method for cleaning a substrate chuck of claim 1, wherein a thickness of the adhesive layer is in the range of 5 µm to 20 µm, and
wherein a thickness of the electrostatic control layer is in the range of 50 µm to 200 µm.

14. The method for cleaning a substrate chuck of claim 1, wherein the plurality of processing chambers includes any one or any combination of a deposition chamber, an oxidation chamber, a heat treatment chamber, an etching chamber, a polishing chamber, or a cleaning chamber.

15. A method for cleaning a substrate chuck, comprising:
loading a cleaning substrate into one of a plurality of processing chambers, the cleaning substrate including an electrostatic control layer and an adhesive layer disposed on one surface of the electrostatic control layer, and a processing chamber of the plurality of processing chambers including the substrate chuck;
controlling the cleaning substrate so that the adhesive layer contacts the substrate chuck; and
reciprocally moving the cleaning substrate in any one or any combination of a vertical direction or a horizontal direction with respect to the support surface of the substrate chuck.

16. The method for cleaning a substrate chuck of claim 15, wherein the electrostatic control layer includes inorganic particles and conductive particles,
wherein the inorganic particles include a piezoelectric material, and
wherein the conductive particles include conductive nanoparticles.

17. The method for cleaning a substrate chuck of claim 15, wherein the substrate chuck includes an electrostatic chuck or a vacuum chuck.

18. The method for cleaning a substrate chuck of claim 17, further comprising, controlling the substrate chuck to not secure the cleaning substrate while the controlling the cleaning substrate and while the reciprocally moving the cleaning substrate.

19. A method for cleaning a substrate chuck, comprising:
loading a cleaning substrate having a ring frame attached thereto into a processing chamber in which the substrate chuck is disposed; and
reciprocally moving the cleaning substrate in any one or any combination of a vertical direction or a horizontal direction on the substrate chuck,
wherein the cleaning substrate includes an electrostatic control layer, and an adhesive layer between the electrostatic control layer and the substrate chuck, and
wherein the electrostatic control layer includes a composite dielectric layer and conductive nanoparticles.

20. The method for cleaning a substrate chuck of claim 19, wherein the composite dielectric layer includes an organic polymer and a piezoelectric material.
